(19) United States
(12) Patent Application Publication
(10) Pub. No.: US 2005/0133863 A1
(43) Pub. Date: Jun. 23, 2005

(54) Semiconductor component arrangement with an insulating layer having nanoparticles

(75) Inventors: Wolfgang Werner, Muenchen (DE); Ralf Otremba, Kaufbeuren (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: Infineon Technologies AG

(21) Appl. No.: 10/916,137

(22) Filed: Aug. 11, 2004

(30) Foreign Application Priority Data
Aug. 11, 2003 (DE) 103 36 747.0

(51) Int. Cl. H01L 27/108

(52) U.S. Cl. 257/341

(57) ABSTRACT

The present invention relates to a semiconductor arrangement which has a layer structure with at least one semiconductor chip, a carrier for the semiconductor chip and an electrically insulating insulating layer, the insulating layer comprising nanoparticles of an electrically insulating material.

### CROSS-REFERENCE TO RELATED APPLICATIONS

This Utility Patent Application claims priority to German Patent Application No. DE 103 36 747.0, filed on Aug. 11, 2003, which is incorporated herein by reference.

### BACKGROUND

The present invention relates to a semiconductor component arrangement with at least one semiconductor chip and at least one insulating layer, which are known in many different actual configurations.

FIGS. 1A-1B illustrate by way of an example of such a semiconductor component arrangement a power transistor integrated in a package of the TO-220 type. The component comprises a transistor chip 11, the back side of which forms the drain terminal of the transistor and on the front side of which there are terminal areas 11A, 11B for the gate terminal and the source terminal of the component. The chip 11 is applied by its back side to a carrier 21, the so-called leadframe, and is connected to it in an electrically conducting manner, for example by soldering or adhesive bonding. The chip 11 is surrounded by an insulating package 41, from which there protrude three leads 21′, 51, 52, which form the external terminals of the component for attachment on a printed circuit board (not represented). One 21′ of the leads forms the drain terminal and is integrally formed on the leadframe 21. The two other leads 51, 52 are respectively connected by means of bonding wires 53, 54 to the gate terminal area 11A and the source terminal area 11B of the chip 11.

In the case of the component represented, heat dissipation can take place by a side of the carrier 21 that is facing away from the chip 11 being attached to a heat sink 60, which is represented only by dashed lines in FIGS. 1A and 1B. In order, in the case of a so-called “Fullpak package,” to avoid this heat sink 60 being connected to the chip 11 in an electrically conducting manner, and consequently being at drain potential, it is known to apply an insulating layer 31 to the side of the leadframe 21 that is facing away from the chip 11, at least in the regions which are to be brought into contact with the heat sink 60.

This insulating layer 31 must offer good thermal conductivity along with adequate mechanical load-bearing capacity, the mechanical load-bearing capacity having to be high enough that the risk of the insulating layer being damaged, for example scratched, during conventional handling of the component is largely avoided.

Until now, the same material that is also used for encapsulating the chip 11 and the leads 21′, 51, 52 to form the package is used for example as the material for the insulating layer 31. Such an encapsulating compound comprises for example a proportion of approximately 20% of an epoxy resin in which particles of an insulating material which make up approximately 80% of the volume of the insulating layer are contained. The diameter of the insulating particles is approximately 5-50 μm, such an insulating layer having a thickness of approximately 0.5 mm to ensure adequate mechanical strength.

Increasing thickness of this insulating layer on the one hand contributes to increasing the mechanical strength, but on the other hand increases the thermal resistance, and consequently impairs the heat dissipation.

### SUMMARY

One embodiment of the present invention provides a semiconductor component arrangement with at least one semiconductor chip, a carrier and an insulating layer which has an improved mechanical strength along with a reduced thickness.

Such a semiconductor component arrangement comprises a layer structure with at least one semiconductor chip, a carrier for the semiconductor chip and an electrically insulating insulating layer, which comprises nanoparticles of an electrically insulating material.

Insulating layers of this type with nanoparticles are distinguished by a high mechanical strength along with a low layer thickness.

Layers containing nanoparticles are known in principle and are described for example in König, Ulf: “Nanostrukturen: Konzepte zur Ressourcenschonung im Auto” (Nanostructures: concepts for conserving resources in automobiles), 2nd IIR technical conference on current applications of nanotechnology, Sep. 17-18, 2002, Cologne, or in Götzen, Rainer; Reinhardt, Andrea: “Rapid Micro Product Development RMPD Schlüsseltechnologie für die Aufbau- und Verbindungstechnik von Mikrosystemen” (Rapid Micro Product Development RMPD key technology for the constructing and connecting technology of microsystems). For use in semiconductor component arrangements, insulating layers containing nanoparticles, which are referred to hereafter as “nano insulating layers”, may in principle comprise the same insulating materials as conventional insulating layers, the particle size of the nano insulating layers being smaller than that of conventional insulating layers, resulting in the increased mechanical load-bearing capacity of these nano insulating layers. The particle diameter, for example, lies in the range between 10 nm and 100 nm, ideally between 50 nm and 100 nm. As in the case of conventional insulating layers, an epoxy resin may serve as the matrix material in which the insulating particles are embedded. The volumetric proportion of the nanoparticles in the overall volume is, for example, between 70% and 90%.

Even from layer thicknesses of approximately 0.1 mm, such a nano insulating layer offers a mechanical strength such as that of a conventional insulating layer, explained above, with a layer thickness of 0.5 mm. However, the reduced thickness of the nano insulating layer results in a distinctly reduced thermal resistance of the insulating layer, and consequently a distinctly improved heat dissipation. It should be pointed out that the reduction in the thickness of the nano insulating layer in comparison with the conventional insulating layer results in a reduced dielectric strength of the nano layer, but that this reduced dielectric strength is adequate for customary applications of such insulating layers. For instance, the dielectric strength of a nano layer of a thickness of 0.1 mm containing nanoparticles of silicon dioxide is approximately 3 kV, which is adequate for many components. Higher dielectric strengths can of course be achieved by increasing the layer thickness.

Unlike in the case of insulating layers previously used in semiconductor component arrangements, nano insulating layers can be applied to the surfaces that are to be insulated by means of spraying, brushing, immersing or spinning, and can consequently be easily processed.

Such nano insulating layers can be used instead of any previously used insulating layers in semiconductor component arrangements or semiconductor modules.

In one embodiment, the nanoparticles, which determine the electrically insulating properties of the nano insulating layer, consist of a semiconductor oxide, such as silicon dioxide for example, a metal oxide, such as zinc oxide, iron oxide or copper oxide for example, or an electrically insulating ceramic. These nanoparticles have good electrical insulating properties, that is, a high electrical resistance, and good thermal conducting properties, that is, a low thermal resistance.

With regard to the arrangement of the insulating layer with respect to the at least one semiconductor chip and the at least one carrier, any desired constellations are conceivable, some of which are explained below.

In one embodiment of the invention, it is provided that the at least one semiconductor chip is applied to the carrier and that the insulating layer is applied to a side of the carrier that is facing away from the semiconductor chip, in order in this way to be able for example to apply the carrier in an electrically insulating manner to a heat sink.

In a further embodiment, it is provided that the arrangement has a second carrier, which adjoins the insulating layer.

Such an arrangement with a first carrier, a nano insulating layer and a second carrier may serve as a replacement for conventional so-called DCB substrates, which usually comprise a copper layer as the first carrier, a ceramic layer as the insulating layer and a copper plate as the second carrier. It is possible for the first carrier layer to be patterned in such a way that it has a number of islands on which semiconductor chips can be respectively arranged, chips on different islands being insulated from one another. In the case of such conventional substrates, the copper plate serves for the heat dissipation.

To produce such a DCB substrate substitute using a nano insulating layer, there is the possibility of providing a carrier layer, for example of copper, of applying the nano insulating layer to this carrier layer, for example by brushing or a spinning process, and of currentlessly depositing a solderable layer, for example a copper layer, onto the nano insulating layer. This solderable layer may be patterned by means of conventional photolithographic techniques. Such a DCB substrate substitute can be produced at lower cost in comparison with a conventional DCB substrate. Although the thermal conductivity of the ceramic layer in the case of conventional substrates is lower than the thermal conductivity of a nano insulating layer, this is in fact compensated by being able to make the nano layer thinner than the conventional insulating layer.

Nano insulating layers can also be used for chip-on-chip arrangements, which have a first and a second semiconductor chip, which are arranged one on top of the other and are separated from one another by an insulating layer. A nano insulating layer may be used as an insulating layer both between the two semiconductor chips and between one of the semiconductor chips and a carrier on which the arrangement with the two chips rests.

A further aspect of the invention relates to the use of a nano insulating layer which contains electrically insulating nanoparticles in a semiconductor component arrangement which has at least one semiconductor chip. The nanoparticles probably have in this case a diameter of between 10 nm and 100 nm, ideally between 50 nm and 100 nm, and may consist of at least one of the following materials: a semiconductor oxide, a metal oxide or a ceramic.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B illustrate a semiconductor component integrated in a TO package with an insulating layer applied to a leadframe.

FIG. 2 illustrates a semiconductor component arrangement with a semiconductor chip applied to a carrier and a heat sink insulated with respect to the carrier by means of a nano insulating layer.

FIG. 3 illustrates a semiconductor component arrangement with two semiconductor chips, which are arranged on a respective first carrier, which are electrically insulated with respect to a further carrier by means of a nano insulating layer.

FIG. 4 illustrates a semiconductor arrangement formed as a chip-on-chip arrangement.

FIG. 5 illustrates an arrangement with two semiconductor chips arranged spaced apart from each other on a carrier and insulated with respect to the carrier.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

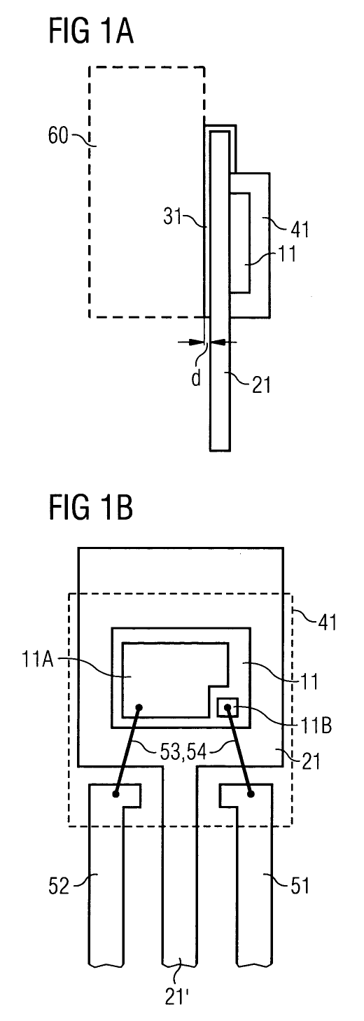

With reference to FIG. 1, already explained at the beginning, a nano insulating layer can be used instead of a conventional insulating layer on the side of the leadframe 21 of a TO package that is facing away from the semiconductor chip 11. This nano insulating layer 31 has for example a thickness of d=0.1 nm and comprises electrically insulating nanoparticles with a diameter of between 10 nm and 100 nm, for example, between 50 nm and 100 nm. The nanoparticles consist, for example, of a semiconductor oxide, such as S:O₂, an iron oxide or a ceramic.

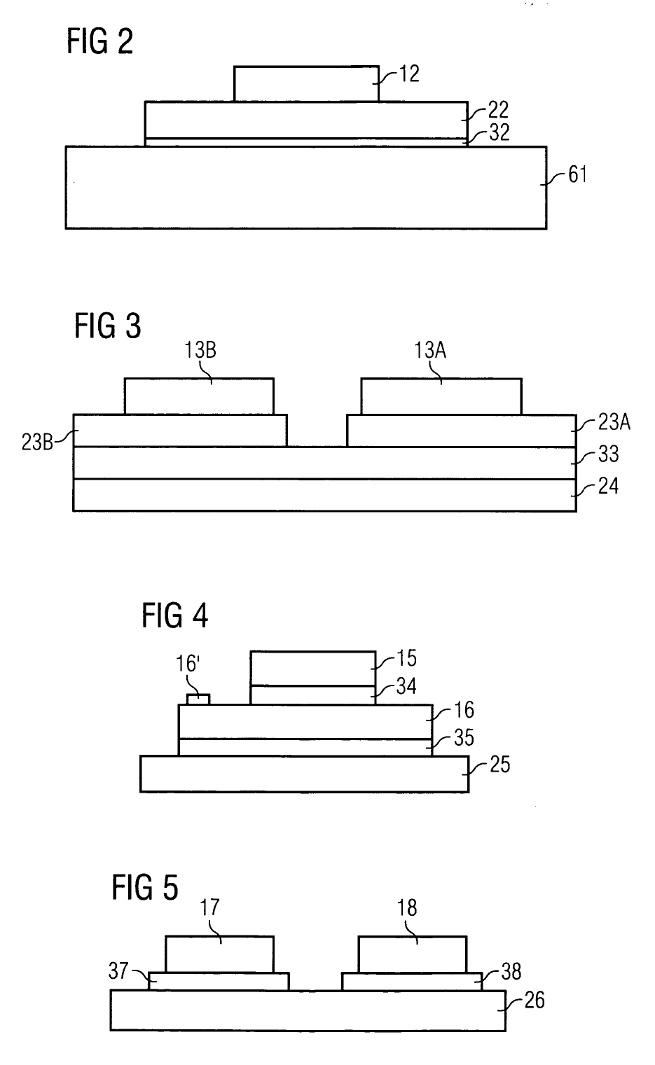

FIG. 2 illustrates a further semiconductor arrangement with a nano insulating layer 32. The semiconductor arrangement comprises a semiconductor chip 12, which is applied to a carrier 22. For heat dissipation, the arrangement with the semiconductor chip 12 and the carrier 22 is arranged on a heat sink 61, the nano insulating layer 32 being arranged between the carrier 22, for example a leadframe, and the heat sink 61. In one embodiment, the semiconductor chip 12 is connected to the carrier 22 in an electrically conducting manner, for example by soldering or adhesive bonding, so that the carrier 22 is at the same potential as the semiconductor chip 12 on the side that is facing the carrier 22. The insulating layer 32 prevents the heat sink 61 from also being at this potential.

FIG. 3 illustrates a further semiconductor arrangement with a nano insulating layer 33. This insulating layer 33 is arranged between two carrier layers 23A, 23B, 24 in the exemplary embodiment. This arrangement with the two carrier layers 23A, 23B and 24 and the nano insulating layer 33 lying between performs the function of a conventional DCB substrate, but by contrast with a DCB substrate can be produced at lower cost. The carrier layer 24, which is located on the side of the substrate that is facing away from the two semiconductor chips 13A, 13B in a way still to be explained, is formed for example as a copper plate and provides good heat dissipation. This carrier plate 24 can be attached for example on a heat sink in a way not represented in any more detail. On this carrier plate 24 there is the nano insulating layer 33, which is applied to the carrier 24 for example by brushing, spraying or by a spinning process. Furthermore, there is also the possibility of coating the plate 24 by immersion in a bath of nano insulating material. Above the nano insulating layer 33, the further carrier layer 23A, 23B, which is for example likewise formed as a copper layer, is applied. This further carrier layer 23A, 23B may for example be currentlessly deposited on the nano insulating layer 33. In the example represented, this carrier layer 23A, 23B is patterned in such a way that it has two island-like portions 23A, 23B, which are separate from each other and on each of which semiconductor chips 13A, 13B are attached, for example by soldering or adhesive bonding.

The patterning of the carrier layer 23A, 23B, which is applied to the nano insulating layer and is usually significantly thinner than the further carrier layer 24, may take place by means of conventional etching processes using photomasks.

The semiconductor chips 13A, 13B arranged on the individual islands 23A, 23B of the carrier layer are in principle electrically insulated from one another and use the same base plate 24 for the heat dissipation. It goes without saying that the semiconductor chips 13A, 13B can be electrically connected to each other in a conventional way by bonding wires or other wiring techniques.

FIG. 4 illustrates a semiconductor arrangement in chip-on-chip technology with two semiconductor chips 15, 16, which are arranged one on top of the other, a nano insulating layer 34 being arranged between the two semiconductor chips 15, 16. The arrangement with the two semiconductor chips 15, 16 and the nano insulating layer 34 is applied to a carrier 25, a further nano insulating layer 35 being arranged between the semiconductor chip 16 that is facing the carrier 25 and the carrier 25.

In the arrangement according to FIG. 4, the two semiconductor chips 15, 16 are electrically insulated from each other, but may be electrically connected to each other by means of conventional bonding wires or other wiring techniques. In the exemplary embodiment represented, the lower 16 of the two semiconductor chips 15, 16 is larger in terms of surface area than the upper 15 of the two semiconductor chips 15, 16, so that contacts 16′ of the lower semiconductor chip 16 may be exposed in the region that is not covered by the upper semiconductor chip 15.

FIG. 5 illustrates a further semiconductor arrangement with two semiconductor chips 17, 18, which are arranged on a common carrier 26. Arranged between each of the semiconductor chips 17, 18 and the carrier 26 is a nano insulating layer 37, 38, in order to insulate the semiconductor chips 17, 18 electrically with respect to the carrier 26.

The present invention uses a nano insulating layer instead of conventional insulating layers in semiconductor arrangements which comprise at least one semiconductor chip.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor component arrangement having a layer structure comprising:
at least one semiconductor chip;
a carrier for the at least one semiconductor chip; and
an electrically insulating insulating layer, wherein the insulating layer comprises nanoparticles of an electrically insulating material.

2. The semiconductor component arrangement of claim 1, wherein the nanoparticles comprise at least one of the following materials: a semiconductor oxide, a metal oxide, and a ceramic.

3. The semiconductor component arrangement of claim 1, wherein the diameter of the nanoparticles is between 10 nm and 100 nm.

4. The semiconductor component arrangement of claim 1, wherein the diameter of the nanoparticles is between 50 nm and 100 nm.

5. The semiconductor component arrangement of claim 1, wherein the at least one semiconductor chip is applied to the carrier and wherein the insulating layer is applied to a side of the carrier that is facing away from the semiconductor chip.

6. The semiconductor component arrangement of claim 5, including a heat sink, which adjoins the insulating layer.

7. The semiconductor component arrangement of claim 5, including a second carrier, which adjoins the insulating layer.

8. The semiconductor component arrangement of claim 1, including a first and a second semiconductor chip, which are arranged one on top of the other, are separated from each other by a first insulating layer and are arranged on the carrier.

9. The semiconductor component arrangement of claim 8, including a second insulating layer arranged between the second semiconductor chip and the carrier.

10. The semiconductor component arrangement of claim 1, wherein the thickness of the insulating layer is less than 0.5 mm.

11. The semiconductor component arrangement of claim 1, wherein the thickness of the insulating layer is less than 0.1 mm.

12. The semiconductor component arrangement of claim 1, wherein the proportion of the nanoparticles in the volume of the insulating layer is between 70% and 90%.

13. A semiconductor component arrangement comprising:
at least one semiconductor chip; and
an insulating layer, which contains electrically insulating nanoparticles.

14. The semiconductor component arrangement of claim 13, wherein the nanoparticles comprise at least one of the following materials: a semiconductor oxide, a metal oxide, and a ceramic.

15. The semiconductor component arrangement of claim 13, wherein the diameter of the nanoparticles is between 10 nm and 100 nm.

16. The semiconductor component arrangement of claim 13, wherein the diameter of the nanoparticles is between 50 nm and 100 nm.

17. The semiconductor arrangement of claim 13, wherein the arrangement is a layer structure.

18. The semiconductor arrangement of claim 13, wherein the arrangement is a layer structure, further including a carrier for the at least one semiconductor chip.

19. The semiconductor arrangement of claim 13, wherein the arrangement is a layer structure, further including a carrier for the at least one semiconductor chip, wherein the at least one semiconductor chip is applied to the carrier and wherein the insulating layer is applied to a side of the carrier that is facing away from the semiconductor chip.

20. The semiconductor arrangement of claim 13, wherein the arrangement is a layer structure, further including a carrier for the at least one semiconductor chip, including a heat sink, which adjoins the insulating layer.
